(19) United States
(12) Patent Application Publication
(10) Pub. No.: US 2024/0167159 A1
(43) Pub. Date: May 23, 2024

(54) METAL ORGANIC CHEMICAL VAPOR DEPOSITION DEVICE

(71) Applicant: TES CO., LTD, Yongin-Si, Gyeonggi-do (KR)

(72) Inventors: Sung-Chul CHOI, Yongin-si, Gyeonggi-do (KR); Kwang-Il CHO, Yongin-si, Gyeonggi-do (KR)

(73) Assignee: TES CO., LTD, Yongin-Si, Gyeonggi-do (KR)

(21) Appl. No.: 18/283,811

(22) PCT Filed: Mar. 27, 2022
(86) PCT No.: PCT/KR2022/004279

§ 371 Date: Sep. 24, 2023

(30) Foreign Application Priority Data
Mar. 30, 2021 (KR) 10-2021-0040802

(51) Int. Cl. C23C 16/455; C23C 16/44; C23C 16/458

(52) U.S. Cl. CPC C23C 16/45591; C23C 16/4408; C23C 16/4583

(57) ABSTRACT

The present disclosure relates to a metal organic chemical vapor deposition apparatus, and more particularly to a metal organic chemical vapor deposition apparatus including a gas supply, which uniformly supplies a process gas and is easily installed and maintained.

### BACKGROUND

### Technical Field

The present disclosure relates to a metal organic chemical vapor deposition apparatus, and more particularly to a metal organic chemical vapor deposition apparatus including a gas supply that uniformly supplies a process gas and is easily installed and maintained.

### Description of the Related Art

A metal organic chemical vapor deposition (MOCVD) apparatus supplies a mixed gas of a group 3 alkyl (organic metal raw material gas) and a group 5 reaction gas with a high-purity carrier gas into a reaction chamber and thermally decomposes the mixed gas on a heated substrate to grow a compound semiconductor crystal. The MOCVD apparatus includes a susceptor mounted on a substrate and injects gas from a side surface to grow a semiconductor crystal on the substrate.

In this case, when a process gas is supplied to a processing space in which a substrate is processed, it is necessary to supply the process gas to the processing space without pre-mixing, and further to uniformly supply the process gas to the processing space.

In the case of a metal organic chemical vapor deposition apparatus according to the related art, it is difficult to install the apparatus because a processing space for processing a substrate has a low and narrow height and the configuration of a gas supply for supplying a process gas is very complicated. For maintenance, the entire gas supply needs to be disassembled and reassembled, and thus it takes a lot of time and money.

### SUMMARY

### Technical Problem

The present disclosure is to resolve this problem and to provide a metal organic chemical vapor deposition apparatus including a gas supply that uniformly supplies a process gas and is easily installed and maintained.

### Technical Solution

To achieve the above object of the present disclosure, provided is a metal organic chemical vapor deposition apparatus including a chamber providing a processing space in which a substrate is processed, a substrate support that is disposed inside the chamber and on which the substrate is accommodated, and a gas supply including a gas provider configured to provide a process gas and a purge gas, and a gas supply connected to the gas provider, configured to guide the process gas to be uniformly supplied to the processing space, and detachably connected to the gas provider, wherein the guide assembly includes a plurality of gas guide plates inclined at a predetermined angle toward the processing space and configured to guide the process gas to the processing space, and a plurality of fixing portions configured to pressurize and fix rear ends of the plurality of gas guide plates.

The fixing portions may include a plurality of first fixing portions that are in contact with upper surfaces of the rear end portions of the plurality of gas guide plates, respectively, and a plurality of second fixing portions that are in contact with lower surfaces of the rear end portions of the plurality of gas guide plates, respectively, and the guide assembly may include a third fixing portion configured to fix a side surface portion of at least one of the plurality of gas guide plates, and a frame portion configured to pressurize and fixe the first fixing portion and the second fixing portion.

A first inclined portion and a second inclined portion may be formed at the same angle as an angle in which the gas guide plates are installed on a lower surface of the first fixing portion and an upper surface of the second fixing portion, respectively.

The metal organic chemical vapor deposition apparatus may further include an additional fixing portion located below the 2^{nd}-3 fixing portion located at a lowermost part among the plurality of second fixing portions and configured to support a lower surface of the 2^{nd}-3 fixing portion.

The first fixing portions located below a 1^{st}-1 fixing portion located at an uppermost part among the plurality of first fixing portions may be configured as a pair and located on both sides of the rear end of the gas guide plate, and a space between the pair of first fixing portions and between the gas guide plates may form a supply portion through which the process gas is supplied.

The metal organic chemical vapor deposition apparatus may further include a barrier lid disposed above the substrate support and providing a processing space with the substrate support, and a front end of a first gas guide plate located at an uppermost part among the plurality of gas guide plates may be connected to the barrier lid.

The front end of the gas guide plate located below the first gas guide plate may extend longer than the first gas guide plate and may be inserted into a space between the substrate support and the barrier lid.

### Advantageous Effects

According to the present disclosure having the above-described configuration, a process gas may be supplied uniformly, installation may be easily performed, and maintenance may be easy.

### BRIEF DESCRIPTION OF THE DRAWING FIGURES

FIG. 1 is a side view of a metal organic chemical vapor deposition apparatus according to an embodiment of the present disclosure.

FIG. 2 is a side cross-sectional view showing the configuration of a gas supply.

FIG. 3 is a perspective view of a gas supply.

FIG. 4 is a side perspective view of a gas supply taken in a longitudinal direction in FIG. 3.

FIG. 5 is an enlarged view of a portion of FIG. 4.

FIG. 6 is a diagram showing one of a second fixing portion.

### DETAILED DESCRIPTION OF THE EXEMPLARY EMBODIMENTS

Hereinafter, a metal organic chemical vapor deposition apparatus according to embodiments of the present disclosure will be described in detail with reference to the drawings.

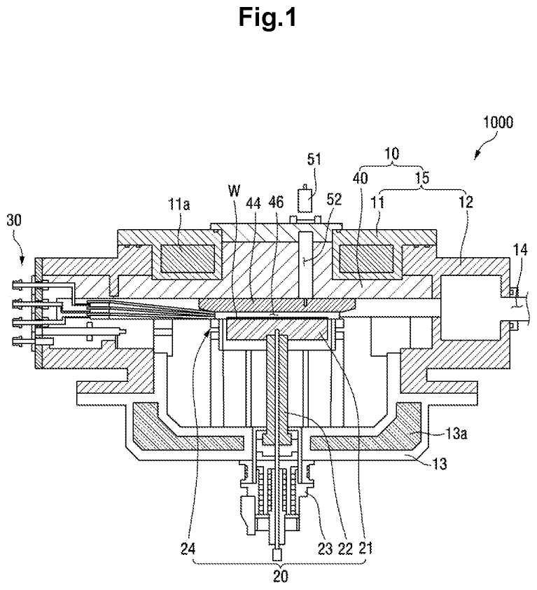

FIG. 1 is a cross-sectional view of a structure of a metal organic chemical vapor deposition apparatus 1000 according to an embodiment of the present disclosure.

Referring to FIG. 1, the metal organic chemical vapor deposition apparatus 1000 includes a chamber 10, a substrate support 20, and a gas supply 30.

The chamber 10 may include an outer chamber 15 and an inner chamber 40 that provides a processing space 46 for processing a substrate W within the outer chamber 15.

The outer chamber 15 includes a chamber lid 11 covering the top, an external wall part 12 fastened to the chamber lid 11 and covering a side of the chamber, and a bottom flange part forming a bottom surface of the chamber. 13.

The chamber lid 11 may be detachably fastened to the external wall part 12 through a fastening element such as a bolt, and a cooling flow passage 11a may be formed in the chamber lid 11. A cooling medium such as cooling water or cooling gas flows through the cooling flow passage 11a to cool the chamber 10 heated by high-temperature heat generated in a deposition process in the chamber 10.

A sensor tube 52 serving as a light measuring passage for an optical sensor 51 for optically measuring a thin film deposited on the substrate W within the inner chamber 40 may be installed in the chamber lid 11. The sensor tube 52 may be disposed through the chamber lid 11 and the inner chamber 40. Here, a purge gas may be introduced into the sensor tube 52 to prevent reaction gas from being discharged from the inner chamber 40 to the sensor tube 52.

The external wall part 12 is fastened to the chamber lid 11 and is configured to cover the side of the inner chamber 40. A vent hole 14 is formed in the external wall part 12, and the vent hole 14 is connected to a gas exhaust line (not shown) to discharge the reaction gas remaining in the processing space 46 after the deposition process is completed to the outside of the chamber 10 through the vent hole 14 and the gas exhaust line (not shown).

The bottom flange part 13 is provided below the outer chamber 15. A cooling flow passage 13a may be formed in the bottom flange part 13. A cooling medium such as cooling water or cooling gas flows through the cooling flow passage 13a to cool the chamber 10 heated by high-temperature heat generated in the deposition process in the inner chamber 40.

The substrate support 20 on which the substrate W is accommodated may be disposed inside the inner chamber 40. The substrate support 20 includes a heating coil 24 for heating the substrate W. For example, the substrate support 20 includes a heater block 21 on which the substrate W is accommodated and heated, a shaft 22 that supports and rotates the heater block 21, a sealing part 23, and the heating coil 24 for heating the substrate W by induction-heating the heater block 21. In this case, the heating coil 24 may be configured to heat a side surface of the heater block 21.

A barrier lid 44 is provided above the substrate support 20. A space between the barrier lid 44 and the heater block 21 corresponds to the processing space 46. A process gas supplied from the gas supply 30 described above may be supplied to the substrate W in the processing space 46. Among the process gases, gases that do not participate in the reaction are discharged to the outside of the chamber 10 through the vent hole 14 and the gas exhaust line (not shown).

A distance between the barrier lid 44 and the heater block 21 is an important factor for smooth processing of the substrate W, and thus may be determined in advance. In this case, since it is not easy to adjust the height of the inner chamber 40 to which the barrier lid 44 is connected, the thickness of the barrier lid 44 may be adjusted to adjust the distance between the barrier lid 44 and the heater block 21.

The gas supply 30 supplies a process gas and a purge gas toward the substrate W disposed in the processing space 46. It is necessary to uniformly supply the process gas toward the substrate W when supplying the process gas.

To this end, the gas supply 30 may include a gas provider 350 providing the process gas and purge gas, and a guide assembly 300 that is connected to the gas provider 350, guides the process gas to be uniformly supplied to the processing space 46, and is detachably connected to the gas provider 350.

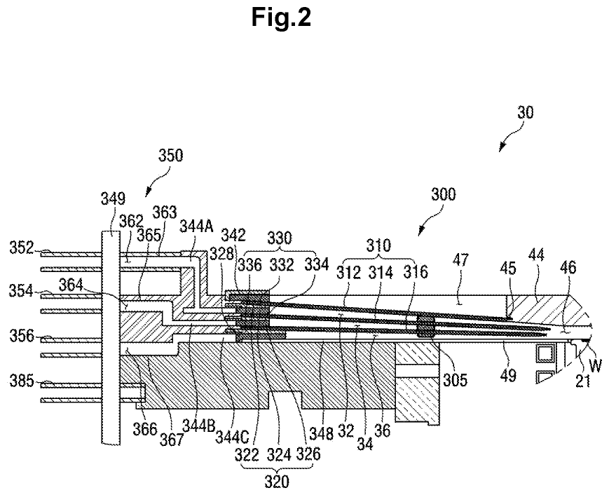

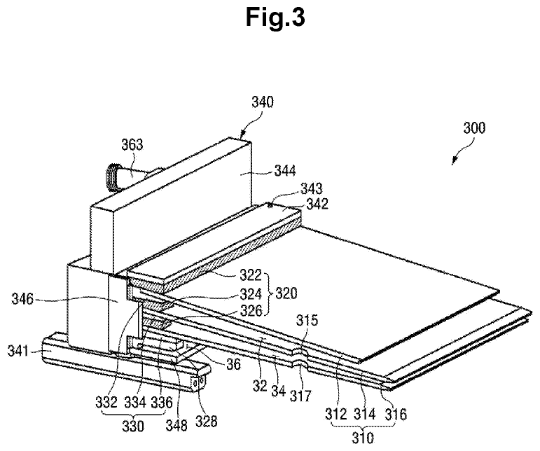

FIG. 2 is a side cross-sectional view showing the configuration of the gas supply 30, and FIG. 3 is a perspective view of the gas supply 30.

Referring to FIGS. 2 and 3, the gas provider 350 serves to supply various gases, including a process gas and a purge gas, to the guide assembly 300.

For example, the gas provider 350 may include a process gas supply source (not shown) storing a process gas, gas inlet ports 352, 354, 356, and 385 connected to the process gas supply source, and connection flow paths 363, 365, and 367 connecting the gas inlet ports 352, 354, 356, and 385 to the guide assembly 300.

The process gas may be configured in a plural number to perform a processing process such as a deposition process for the substrate W, and accordingly, a plurality of process gas supply sources may be provided.

The gas inlet ports 352, 354, 356, and 385 may be respectively connected to the plurality of process gas supply sources and may be supported by being connected to a support frame 349.

The plurality of gas inlet ports 352, 354, 356, and 385 may include the gas inlet ports 352, 354, and 356 to which a process gas is supplied, and the purge gas inlet port 385 to which a purge gas is supplied. The gas inlet ports 352, 354, and 356 are shown as three, but are not limited thereto and may be adjusted appropriately.

The gas inlet ports 352, 354, and 356 may be connected to the guide assembly 300 through the connection flow paths 363, 365, and 367. The connection flow paths 363, 365, and 367 may provide flow spaces 362, 364, and 366 therein through which the process gas is provided to the guide assembly 300.

The guide assembly 300 uniformly supplies the supplied process gas toward the substrate W within the processing space 46 to smoothly and repeatedly reproduce the processing process for the substrate W.

For example, the guide assembly 300 may include a plurality of gas guide plates 310 that are inclined at a predetermined angle toward the processing space 46 and guide the process gas to the processing space 46, and a plurality of fixing portions 320 and 330 that pressurize and fix rear ends of the plurality of gas guide plates 310. The fixing portions 320 and 330 may include a plurality of first fixing portions 320 that fix the plurality of gas guide plates 310 by making surface contact with and pressurizing upper surfaces of the rear ends of the plurality of gas guide plates 310, respectively, and a plurality of second fixing portions 330 that fix the plurality of gas guide plates 310 by making surface contact with and pressurizing lower surfaces of the rear ends of the plurality of gas guide plates 310, respectively.

The guide assembly 300 may further include a third fixing portion 305 that fixes side surface portions of the plurality of gas guide plates 310, and a frame portion 340 that pressurizes and fixes the first fixing portion 320 and the second fixing portion 330.

The frame portion 340 may include a flow path frame 344 that is connected to the connection flow paths 363, 365, and 367 and includes internal flow paths 344A, 344B, and 344C in which a process gas flows, an upper frame 342 that pressurizes the first fixing portion 320 and the second fixing portion 330 from the above, a lower frame 348 that pressurizes the first fixing portion 320 and the second fixing portion 330 from the below, a side frame 346 connecting the upper frame 342 to the lower frame 348, and a base frame 341.

The flow path frame 344 may be connected to the aforementioned connection flow paths 363, 365, and 367 and may supply a process gas toward the gas guide plates 310. To this end, the internal flow paths 344A, 344B, and 344C in which the process gas flows are formed within the flow path frame 344. The internal flow paths 344A, 344B, and 344C are formed corresponding to the number of the connection flow paths 363, 365, and 367. In this case, when the number of the internal flow paths 344A, 344B, and 344C needs to be changed, the number of internal flow paths may be adjusted by dividing a frame body of the flow path frame 344 or assembling frames in a stacked form.

The upper frame 342 and the lower frame 348 pressurize the first fixing portion 320 and the second fixing portion 330 from the above and below, respectively. For example, the upper frame 342 and the lower frame 348 are fastened with an upper bolt 343 and a lower bolt (not shown) and pressurize the first fixing portion 320 and the second fixing portion 330, and thus the gas guide plates 310 are fixedly disposed and inclined at a predetermined angle.

In this case, the upper frame 342 and the lower frame 348 are connected at side surfaces thereof by the side frame 346, and thus the first fixing portion 320, the second fixing portion 330, and the gas guide plates 310 may be prevented from being horizontally twisted and may be fixed.

The base frame 341 may be provided at a lower part of the frame portion 340, and may be connected to a chamber 10 by the base frame 341.

When a plurality of process gases are supplied, it is necessary that the process gases are not mixed in advance but are mixed after being supplied to the processing space 46. Therefore, a gas introduction space 47 is needed to separately supply the process gas to the processing space 46. For example, the gas introduction space 47 may be defined as a space between the aforementioned internal chamber 40 and a gas introduction plate 49.

However, a distance between the barrier lid 44 and the heater block 21, which corresponds to the processing space 46, may be very small to smoothly perform the processing process for the substrate W.

Therefore, to guide the process gas from the gas introduction space 47, which occupies a relatively large space, to the processing space 46, which has a relatively narrow space and height, the gas guide plates 310 that guide the process gas need to be placed to be inclined at an appropriate angle.

In FIGS. 2 and 3, the gas guide plates 310 may be inclined downward at a predetermined angel and may extend toward the processing space 46.

In this case, an inclination angle of at least one of the plurality of gas guide plates 310 may be different from an inclination angle of another gas guide plate 310.

For example, an inclination angle of a first gas guide plate 312 located at the top among the plurality of gas guide plates 310 may be relatively largest, and an inclination angle of a third gas guide plate 316 located at the bottom among the plurality of gas guide plates 310 may be relatively smallest. However, an angle of the gas guide plates 310 may be appropriately changed depending on the arrangement and size of the gas introduction space 47 and the processing space 46.

The length of at least one of the plurality of gas guide plates 310 may be different from the length of another gas guide plate 310.

For example, among the plurality of gas guide plates 310, the length of the first gas guide plate 312 located at the top is the shortest, and the lengths of a second gas guide plate 314 and the third gas guide plate 316 that are located below the first gas guide plate 312 may be relatively long. That is, front ends of the second gas guide plate 314 and the third gas guide plate 316 may extend longer than the first gas guide plate 312 and may be inserted into a space between the barrier lid 44 and the heater block 21.

As described above, this is because the height of the processing space 46 is smaller than the height of the gas introduction space 47 and it difficult for front ends of all the gas guide plates 310 to be inserted into a space between the barrier lid 44 and the heater block 21.

In this case, a front end of the first gas guide plate 312 may be connected to the barrier lid 44. For example, a fixing groove 45 may be formed in the barrier lid 44, and the front end of the first gas guide plate 312 may be fixedly inserted into the fixing groove 45 to maintain an inclination angle of the first gas guide plate 312.

The front ends of the second gas guide plate 314 and the third gas guide plate 316 are inserted into a space between the barrier lid 44 and the heater block 21, and thus are not supported by the barrier lid 44. In this case, the front ends of the second gas guide plate 314 and the third gas guide plate 316 may sag downward.

According to the present disclosure, the third fixing portion 305 fixing at least one side surface portion among the plurality of gas guide plates 310 may be provided to prevent the front ends of the second gas guide plate 314 and the third gas guide plate 316 from sagging.

For example, side surface grooves 315 and 317 may be formed in side surface portions of the second gas guide plate 314 and the third gas guide plate 316, respectively. In this case, fixing protrusions (not shown) inserted into the side surface grooves 315 and 317 may be formed on the third fixing portion 305. When the second gas guide plate 314 and the third gas guide plate 316 are installed, the side surface portions of the second gas guide plate 314 and the third gas guide plate 316 may be supported by the third fixing portion 305, and thus the second gas guide plate 314 and the third gas guide plate 316 may be prevented from sagging beyond a preset angle.

According to the present embodiment, the gas guide plates 310 may be made of quartz, but the material is not particularly limited, and the gas guide plates 310 may be made of metal.

When the gas guide plates 310 are inclined at a predetermined angle, upper and lower portions of a rear end of the gas guide plates 310 are fixed to maintain an angle of the gas guide plates 310.

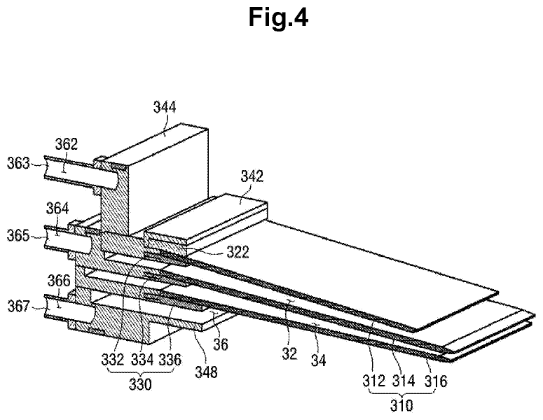

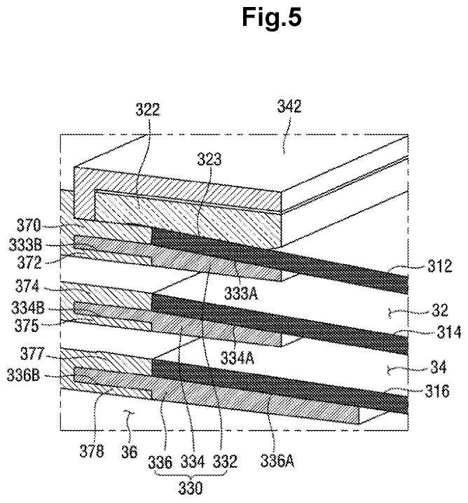

FIG. 4 is a side perspective view of the gas supply 30 taken in a longitudinal direction in FIG. 3, and FIG. 5 is an enlarged view of a portion of FIG. 4.

Referring to FIGS. 2, 4, and 5, the first fixing portion 320 may be disposed above the plurality of gas guide plates 310 to pressurize and fix an upper surface of the rear end of the gas guide plates 310. The second fixing portion 330 may be disposed below the plurality of gas guide plates 310 to pressurize and fix a lower surface of the rear end of the gas guide plates 310.

The first fixing portion 320 and the second fixing portion 330 may be made of synthetic resin. For example, the first fixing portion 320 and the second fixing portion 330 may be made of engineering plastic or super engineering plastic. In addition, the first fixing portion 320 and the second fixing portion 330 are formed of one or a combination of two or more selected from polysulfone (PSU), polyarylate (PAR), polyetherimide (PEI), polyethersulfone (PES), and polyphenylene sulfone (PPS), polyimide (PI), teflon (PTFE), and polyetheretherketone (PEEK).

According to the present disclosure, the first fixing portion 320 and the second fixing portion 330 may be made of synthetic resins with different strengths. For example, the first fixing portion 320 may be made of Teflon, and the second fixing portion 330 may be made of polyimide, and vice versa.

This is because, when both the first fixing portion 320 and the second fixing portion 330 are made of high-strength synthetic resin and the gas guide plates 310 are pressurized, the gas guide plates 310 may be deformed or damaged. In particular, when the gas guide plates 310 are made of quartz, the gas guide plates 310 may be easily damaged and broken.

Therefore, when the first fixing portion 320 and the second fixing portion 330 are pressurized by the frame portion 340 by varying the strengths of the first fixing portion 320 and the second fixing portion 330, the gas guide plates 310 may be prevented from being damaged and broken by absorbing deformation due to pressurization by a fixing portion with a relatively low strength.

A 1^{st}-1 fixing portion 322 located at the uppermost part among the plurality of first fixing portions 320 pressurizes an upper surface of a rear end of the first gas guide plate 312. A second 1^{st}-2 fixing portion 324 is disposed between a 2^{nd}-1 fixing portion 332 and the second gas guide plate 314 to pressurize an upper surface of a rear end of the second gas guide plate 314. A 1^{st}1-3 fixing portion 326 is disposed between a 2^{nd}-2 fixing portion 334 and the third gas guide plate 316 to pressurize an upper surface of a rear end of the third gas guide plate 316.

The 2^{nd}-1 fixing portion 332 located at the uppermost part among the plurality of second fixing portions 330 is disposed between the first gas guide plate 312 and the 1^{st}-2 fixing portion 324 to pressurize a lower surface of the rear end of the first gas guide plate 312. The 2^{nd}-2 fixing portion 334 is disposed between the second gas guide plate 314 and the 1^{st}1-3 fixing portion 326 to pressurize a lower surface of the rear end of the second gas guide plate 314. A 2^{nd}-3 fixing portion 336 pressurizes a lower surface of the rear end of the third gas guide plate 316 from a lower part of the third gas guide plate 316.

In this case, to support the 2^{nd}-3 fixing portion 336, an additional fixing portion 328 may be further provided. That is, the additional fixing portion 328 may be located below the 2^{nd}-3 fixing portion 336 to support the 2^{nd}-3 fixing portion 336 from the below. The additional fixing portion 328 may be supported by the aforementioned base frame 341 and gas introduction plate 49.

As described above, the gas guide plates 310 may be inclined and placed at a predetermined angle toward the processing space 46. In this structure, when the first fixing portion 320 and the second fixing portion 330 pressurize the upper or lower surface of the rear end of the gas guide plates 310 by a horizontal surface, the front end of the gas guide plates 310 is lifted and twisted at a predetermined angle.

Therefore, a first inclined portion 323 and second inclined portions 333A, 334A, and 336A may be formed at the same angle as an angle at which the gas guide plates 310 is installed on the lower surface of the first fixing portion 320 and the upper surface of the second fixing portion 330.

The first inclined portion 323 of the first fixing portion 320 and the second inclined portions 333A, 334A, and 336A of the second fixing portion 330 may be inclined at the same angle as the angle at which the gas guide plates 310 are installed. Thus, when the first fixing portion 320 and the second fixing portion 330 are pressurized by the upper frame 342 and the lower frame 348 from the above and below, respectively, the inclined angle of the gas guide plates 310 may also be maintained to be same angle as a predetermined angle.

In addition, by the first inclined portion 323 and the second inclined portions 333A, 334A, and 336A, the first fixing portion 320 and the second fixing portion 330 are in surface contact with the gas guide plates 310, respectively, to increase a contact area, thereby preventing the gas guide plates 310 from being separated by friction and firmly fixing the gas guide plates 310.

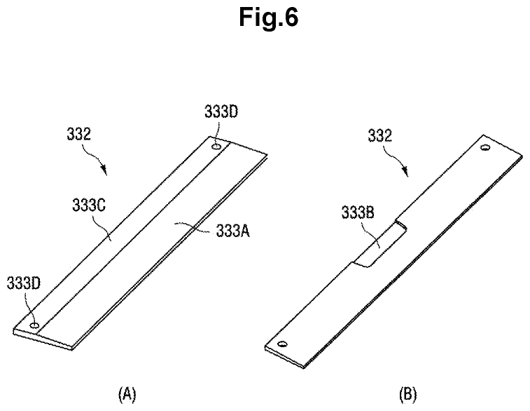

FIG. 6 is a diagram showing the 2^{nd}-1 fixing portion 332. FIG. 6A is an upper perspective view of the 2^{nd}-1 fixing portion 332, and FIG. 6B is a lower perspective view of the 2^{nd}-1 fixing portion 332.

Referring to FIG. 6, the 2^{nd}-1 fixing portion 332 may include the aforementioned second inclined portion 333A, and a body portion 333C connected to the second inclined portion 333A. The body portion 333C may include fastening holes 333D at both side portions. The upper bolt 343 fastening the upper frame 342 may be passed through and fastened through the fastening hole 333D.

A first recess 333B may be formed on a lower surface of the 2^{nd}-1 fixing portion 332. The first recess 333B may be formed with a predetermined width and depth on the lower surface of the body portion 333C.

Referring to FIGS. 4 to 6, when the 2^{nd}-1 fixing portion 332 is mounted on the guide assembly 300, the 2^{nd}-1 fixing portion 332 may be fixedly inserted into and close contact with a lower surface of a first frame 370 of the frame portion 340. In this case, a first protrusion 372 protruding from the center of the first frame 370 is inserted into the first recess 333B to support the 2^{nd}-1 fixing portion 332.

A second recess 334B and a third recess 336B are also respectively formed in the 2^{nd}-2 fixing portion 334 and the 2^{nd}-3 fixing portion 336 mounted below the 2^{nd}-1 fixing portion 332. Accordingly, when the 2^{nd}-2 fixing portion 334 and the 2^{nd}-3 fixing portion 336 are mounted on the guide assembly 300, the 2^{nd}-2 fixing portion 334 and the 2^{nd}-3 fixing portion 336 are fixedly inserted in close contact with lower surfaces of a second frame 374 and a third frame 377 of the frame portion 340, respectively. In this case, a second protrusion 375 and a third protrusion 378 protruding from the central portions of the second frame 374 and the third frame 377 are inserted into the second recess 334B and the third recess 336B, respectively, to support the 2^{nd}-2 fixing portion 334 and the 2^{nd}-3 fixing portion 336.

The case of installing the gas guide plates 310 will be described below. First, in a state in which the 2^{nd}-3 fixing portion 336 is installed, the third gas guide plate 316 is inserted along an upper surface of the 2^{nd}-3 fixing portion 336. In this case, the rear end of the third gas guide plate 316 comes in contact with the front end of the third frame 377, and a protrusion length of the third gas guide plate 316 is determined. Although not shown in the drawing, the front end of the third frame 377 may be formed to be inclined corresponding to an installation inclination of the third gas guide plate 316. As a result, the front end of the third frame 377 may be firmly supported by making surface contact with the rear end of the third gas guide plate 316 to increase a contact area.

Likewise, when the second gas guide plate 314 and the first gas guide plate 312 are installed, the rear end of each gas guide plate comes in contact with the front end of the second frame 374 and the first frame 370, thereby determining the protrusion length. The front ends of the second frame 374 and the first frame 370 may also be formed to be inclined corresponding to an installation inclination of the second gas guide plate 314 and the first gas guide plate 312.

The 1^{st}-1 fixing portion 322 may extend long enough to cover an entire upper surface of the rear end of the first gas guide plate 312. However, when the 1^{st}-2 fixing portion 324 and the 1^{st}1-3 fixing portion 326 are formed similarly to the 1^{st}-1 fixing portion 322, it is difficult to provide a supply port for supplying a process gas.

Therefore, among the plurality of the first fixing portions 320, the 1^{st}-2 fixing portion 324 and the 1^{st}1-3 fixing portion 326 that are located below the 1^{st}-1 fixing portion 322 located at the uppermost part and the additional fixing portion 328 may be configured as a pair and may be located on both sides of the rear end of the gas guide plate 310.

That is, as shown in FIG. 4, a space between the first gas guide plate 312 and the second gas guide plate 314 and between the pair of the 1^{st}-2 fixing portion 324 may form a first supply port 32 through which a first process gas is supplied. A space between the second gas guide plate 314 and the third gas guide plate 316 and between the pair of the 1^{st}1-3 fixing portion 326 forms a second supply port 34 through which a second process gas is supplied, and a space between the third gas guide plate 316 and the gas introduction plate 49 and between the pair of additional fixing portions 328 forms a third supply port 36 through which the third process gas is supplied.

While the present disclosure has been described referring to the exemplary embodiments of the present disclosure, those skilled in the art will appreciate that many modifications and changes can be made to the present disclosure without departing from the spirit and essential characteristics of the present disclosure. Therefore, if the modifications basically include the elements of the claims of the present disclosure, all of them are considered to be included in the technical scope of the present disclosure.

What is claimed is:

1. A metal organic chemical vapor deposition apparatus comprising:
a chamber providing a processing space in which a substrate is processed;
a substrate support that is disposed inside the chamber and on which the substrate is accommodated; and
a gas supply including a gas provider configured to provide a process gas and a purge gas, and a guide assembly connected to the gas provider, configured to guide the process gas to be uniformly supplied to the processing space, and detachably connected to the gas provider,
wherein the guide assembly includes a plurality of gas guide plates inclined at a predetermined angle toward the processing space and configured to guide the process gas to the processing space, and a plurality of fixing portions configured to pressurize and fix rear ends of the plurality of gas guide plates.

2. The metal organic chemical vapor deposition apparatus of claim 1, wherein the fixing portions include a plurality of first fixing portions that pressurize and fix by contacting with upper surfaces of the rear end portions of the plurality of gas guide plates, respectively, and a plurality of second fixing portions that pressurize and fix by contacting with lower surfaces of the rear end portions of the plurality of gas guide plates, respectively; and
wherein the guide assembly includes a third fixing portion configured to fix a side surface portion of at least one of the plurality of gas guide plates, and a frame portion configured to pressurize and fixe the first fixing portion and the second fixing portion.

3. The metal organic chemical vapor deposition apparatus of claim 2, wherein a first inclined portion is formed at the same angle as an angle in which the gas guide plates are installed on a lower surface of the first fixing portion, and a second inclined portion is formed at the same angle as an angle in which the gas guide plates are installed on an upper surface of the second fixing portion, respectively

4. The metal organic chemical vapor deposition apparatus of claim 2, further comprising:
an additional fixing portion located below the 2nd-3 fixing portion located at a lowermost part among the plurality of second fixing portions and configured to support a lower surface of the 2nd-3 fixing portion.

5. The metal organic chemical vapor deposition apparatus of claim 2, wherein the first fixing portions located below a 1st-1 fixing portion located at an uppermost part among the plurality of first fixing portions are configured as a pair and located on both sides of the rear end of the gas guide plate; and
wherein a space between the pair of first fixing portions and between the gas guide plates forms a supply portion through which the process gas is supplied.

6. The metal organic chemical vapor deposition apparatus of claim 2, further comprising:
a barrier lid disposed above the substrate support and providing a processing space with the substrate support,
wherein a front end of a first gas guide plate located at an uppermost part among the plurality of gas guide plates is connected to the barrier lid.

7. The metal organic chemical vapor deposition apparatus of claim 6, wherein a front end of the gas guide plate located below the first gas guide plate extends longer than the first gas guide plate and is inserted into a space between the substrate support and the barrier lid.
